(19) United States
(12) Patent Application Publication
(10) Pub. No.: US 2026/0029495 A1
(43) Pub. Date: Jan. 29, 2026

(54) End Stage System for a Gradient Amplifier

(71) Applicant: Siemens Healthineers AG, Forchheim (DE)

(72) Inventor: Franz Schork, Burgthann (DE)

(73) Assignee: Siemens Healthineers AG, Forchheim (DE)

(21) Appl. No.: 19/279,168

(22) Filed: Jul. 24, 2025

(30) Foreign Application Priority Data
Jul. 26, 2024 (EP) 24191212.0

(51) Int. Cl. G01R 33/385

(52) U.S. Cl. CPC G01R 33/3852

(57) ABSTRACT

An end stage system for a gradient amplifier comprising a plurality of end stages for different gradient coils, wherein each of the end stages has a plurality of cylinders and wherein each cylinder comprises at least one circuit composed of a capacitor unit and at least one bridge unit, wherein a plurality of bridge units are interconnected in series as an end stage output, and wherein bridge units of at least two different end stages are connected to the same capacitor unit.

### TECHNICAL FIELD

The aspects of the disclosure relate to an end stage system for a gradient amplifier, a method for controlling an end stage system, a gradient system for a magnetic resonance tomography system, and a magnetic resonance tomography system.

### BACKGROUND

In the field of magnetic resonance tomography (MRT), magnetic fields known as gradient fields are required in addition to the strong main magnetic field. Although these fields are not as strong as the main magnetic field, a comparatively high power is required nonetheless. The gradient fields are generated by means of gradient coils. The latter are typically aligned linearly to the X-axis, Y-axis, and Z-axis independently of one another and are often referred to as X, Y, and Z gradient coils.

In order to generate three mutually independent gradient current pulses (for the X-, Y-, and Z-axis) by means of a gradient coil, a device known as a gradient (power) amplifier (GPA) is used to generate the power necessary for this. Since the gradient pulses typically vary at a specified slew rate, the GPA must be able to emit this current slope and a suitable current amplitude in order to build an acceptable field for the imaging by way of the gradient coils.

In the prior art, the concept shown in FIG. 3 was used for generating the independent current pulses in the GPA. For each axis, the power for the respective gradient coil is provided in what is termed an “end stage”. Each end stage typically comprises three to five secondary systems, called “cylinders”, which are galvanically isolated from one another by means of transformers and can be switched according to the current pulse requirement.

Each cylinder typically comprises a circuit composed of a current conversion unit (usually a rectifier), a capacitor unit constantly charged by the current conversion unit, and a bridge unit which is electrically connected to the capacitor unit and is generally an H-bridge or an H-bridge system. By interconnecting the cylinders, more precisely, the bridge units of an end stage, a multiple of the voltage available from one current conversion unit can be generated.

Even when separate transformers can be used for each cylinder, a transformer having one secondary winding per cylinder is often used. Per axis, this results in one end stage for X, one for Y, and one for Z. In the final configuration stage, the transformer possesses nine secondary systems for three-cylinder GPAs, and fifteen secondary systems for five-cylinder GPAs.

A galvanic isolation does not necessarily have to be realized by means of a transformer. It is also possible to use DC/DC converters or AC/DC converters, which then generate the required voltage directly or switch a plurality of converters one above the other. A disadvantageous aspect of the converter concept compared with the transformer is the low overload capability, which is necessary specifically in the case of high short-duration current pulses. With converters, this must be compensated for by means of very large capacitances or an overall higher performance class, which, in view of high cost pressure and at the same time low construction volume, brings this concept quickly to the limits of what is feasible.

### SUMMARY

It is an object of the present disclosure to disclose an end stage system for a gradient amplifier, a method for controlling an end stage system, a gradient system for a magnetic resonance tomography system, and a magnetic resonance tomography system by means of which the above-described disadvantages are avoided.

This object is achieved by means of an end stage system according to claim 1, a method according to claim 10, a gradient system according to claim 12, and a magnetic resonance tomography system according to claim 13.

An end stage system according to the disclosure for a gradient amplifier comprises a plurality of end stages for different gradient coils, wherein each of the end stages has a plurality of cylinders and wherein each cylinder comprises at least one circuit composed of a capacitor unit and at least one bridge unit, wherein a plurality of bridge units are interconnected in series as an end stage output, and wherein bridge units of at least two different end stages are connected to the same capacitor unit.

The capacitor units of the cylinders are generally supplied with energy, i.e., charged, by transformers (in most cases, a secondary winding per cylinder on a shared magnetic yoke of a transformer). In this case, the alternating current is typically converted into direct current by means of a current conversion unit. The current conversion unit is typically a rectifier, but can also be realized by means of other components (for example, final control elements). Circuits for charging the capacitor unit are very well known in the prior art, and no further detailed explanation is given here. For each cylinder, therefore, the capacitor unit connected to it is constantly charged, and the bridge units tap the charges of the individual capacitor units for the purpose of shaping the gradient signal. In this arrangement, the four inputs of the H-bridge(s) of the bridge units are connected in pairs to the capacitor unit and the two outputs are each connected in series such that, with three bridge units, the first output of the first bridge unit forms the end stage output “−”, the second output of the first bridge unit is connected to the first output of the second bridge unit, the second output of the second bridge unit is connected to the first output of the third bridge unit, and the second output of the third bridge unit forms the end stage output “+”. It should be noted here that “+” and “−” do not necessarily indicate the technical current direction but are merely intended to serve for differentiating the two terminals for a gradient coil. A gradient coil can then be connected to the two end stage outputs. This interconnection arrangement is well known in the prior art.

The difference of the aspects of the disclosure compared to the prior art thus lies in the fact that a circuit composed of the capacitor unit (and consequently also preferably of a current conversion unit) is used for a plurality of bridge units of different end stages. This can be envisioned such that initially, a conventional GPA consisting of three end stages, each having three cylinders per end stage, is considered. In each end stage, there is a first, second and third bridge unit. If the second bridge unit of each end stage is now connected to the same capacitor unit, the cylinders are interconnected to form an aspect for an end stage system according to the disclosure. This would save two cylinder parts, specifically altogether two capacitor units (i.e., two power capacitors) and, where applicable, also two current conversion units (in particular rectifiers).

Basically, the end stage system according to the aspects of the disclosure saves cylinders because the main part of the cylinder which accounts for volume, weight and costs, specifically the (optional) current conversion unit and the capacitor unit, are used for a plurality of bridge units. What is important in this arrangement is that bridge units of at least two different end stages (i.e., for different gradient coils) are connected to the same capacitor unit (and hence, where applicable, also to the same current conversion unit).

In practice, a cylinder often has a transformer winding, a rectifier, a DC link capacitor and an H-bridge. These are then installed together with other cylinders in an end stage, which can be envisioned as a metal box containing the components. The individual cylinders are then supplied directly (if rectifiers are integrated in the end stage) by the secondary windings of the transformer. Since in high-powered GPAs the rectifiers often no longer fit in the end stage box for space reasons, the rectifiers are then swapped out.

As a result of the shared use of one capacitor unit (or several), the situation may now occur that gradient coils are connected to one another by means of special switch settings of the bridge units. A short-circuit of a capacitor unit could also be switched or two capacitor units shorted with one another. This is not desirable. This can also happen in the prior art, for example when all the switches of a bridge unit are switched. Care should therefore be taken to ensure that special switch settings (“forbidden switching combinations”), which are well known, do not occur. This can be achieved quite simply by means of an interconnection with logic gates or a correspondingly designed software implementation.

Furthermore, care should be taken that initially it is not specified which switch is to switch which bridge unit, and when. Rather, at the start a target current profile is specified by means of which the desired gradient fields are to be generated. From this, a control logic derives switching patterns for the bridge units. A fixed interconnection arrangement in this case is that certain switching states of each H-bridge of the bridge units (namely both switches of the same outputs switched) are forbidden. It may well be that the same setpoint signal demands other switching combinations because other disturbance variables (temperature, noise, etc.) are present at the respective points in time. The feedback control system detects this by means of a comparison of the setpoint with the actual value and rectifies this deviation using a different switch combination. This process is prior art.

A method according to the aspects of the disclosure serves for controlling an end stage system according to the disclosure. The method comprises the following steps:
specifying a list or table of forbidden switching combinations for the bridge units of the end stage system,
receiving a data stream having a target current profile for an examination,
determining target switch combinations with which the bridge units must be switched in order to achieve the target current profile,
outputting control commands for switching the switches of the bridge units according to the target switching combinations, wherein forbidden switching combinations are suppressed.

If, in each bridge unit, the first switch of the first output has the number “1”, the second switch of the first output the number “2”, the first switch of the second output the number “3” and the second switch of the second output the number “4”, then the switching combinations 1+2 and 2+3 of each H-bridge would be forbidden (prior art). A novel addition with the aspects of the disclosure is that switch settings of different end stages are also forbidden, namely X1+Y2, X2+Y1, X2+Y3, X3+Y2, X3+Y4 and X4+Y3 and also X1+Z2, X2+Z1, X2+Z3, X3+Z2, X3+Z4 and X4+Z3 as well as Y1+Z2, Y2+Z1, Y2+Z3, Y3+Z2, Y3+Z4 and Y4+Z3.

A gradient system according to the aspects of the disclosure for a magnetic resonance tomography system comprises a number of gradient coils and an end stage system according to the aspects of the disclosure, wherein one gradient coil is in each case connected to an end stage output of an end stage of the end stage system.

A magnetic resonance tomography system according to the aspects of the disclosure comprises a gradient system according to the aspects of the disclosure.

Further particularly advantageous aspects and developments of the aspects of the disclosure will become apparent from the dependent claims as well as from the following description, wherein the claims of one claims category can also be developed analogously to the claims and parts of the description relating to a different claims category, and wherein in particular also individual features of different exemplary aspects or variants can be combined to form new exemplary aspects or variants.

A preferred end stage system is characterized in that the gradient amplifier comprises at least three end stages and at least one bridge unit of each of the end stages is connected to the same capacitor unit. There therefore exists one end stage for an X gradient coil, one end stage for a Y gradient coil and one end stage for a Z gradient coil. One bridge unit of each end stage in each case shares a capacitor unit with bridge units of the respective other end stages. This can apply to one bridge unit of each end stage in each case or to a plurality of bridge units. The end stage system may be embodied as part of the gradient amplifier or comprise the gradient amplifier.

It is preferred in this regard that a first bridge unit in each case of each of the end stages is connected to the same first capacitor unit, and in addition a second bridge unit (different from the first bridge unit) in each case of each of the end stages is connected to the same second capacitor unit (different from the first capacitor unit). The more bridge units share a capacitor unit, the more electronic components of the cylinders (capacitor units and, where applicable, current conversion units) can be saved.

A preferred end stage system is characterized in that each end stage output comprises the same number of bridge units interconnected in series, preferably at least three, five or seven. Even-numbered cylinder arrangements could also be present, though odd-numbered are preferred.

A preferred end stage system is characterized in that the series connection of the bridge units of each end stage output has a functional order which is determined by the magnetic fields of gradient coils connected according to specification to the end stages. In a series connection having a predefined current direction, a functional order would be for example the sequence of the components in the current direction. Since the current can flow in both directions in gradient coils, a suitable order could also be dependent on the magnetic field of the gradient coils in the direction of the coordinate axes of the MRT system.

It is preferred in this case that bridge units of at least two different end stages, which are connected to the same capacitor unit, are, in each case, bridge units of the same or similar type in terms of their position in the order. Although this is not absolutely necessary, it is very advantageous for the shaping of magnetic fields of the gradient coils.

In a preferred end stage system, at least one bridge unit of each of the end stages is galvanically isolated from the other end stages. Such a galvanic isolation reduces the number of forbidden switch settings. The galvanic isolation preferably relates to a bridge unit at the start or at the end of the series connection of the end stage in question. This is likewise very advantageous for reducing forbidden switching states.

A preferred end stage system comprises a locking system that prevents, in particular blocks, specified switching combinations of the bridge units. It is preferred in this case that the locking system is designed to suppress, or not to generate in the first place, switching combinations which
lead to a short circuit between the terminals of a capacitor unit,
lead to a direct connection between the terminals of two capacitor units, or
lead to load short circuits (connection of two gradient coils).

A preferred end stage system is characterized in that the locking system for each switching signal of a switch of a bridge unit (typically four switching signals per bridge unit for the four switches of the H-bridge) comprises a lock unit (as part of a locking unit) comprising an arrangement of logic gates (hardware gates or implemented in software). These gates are in particular AND gates and/or NAND gates, preferably an AND gate with an additional inverting output and multiple inputs. In this case, each lock unit preferably comprises an input for a switching signal and a number of inputs for lock signals, as well as an output for the switching signal and preferably an output for the inverted switching signal. It is preferred in this case that the outputs of the lock units of the locking system are connected to the inputs of other lock units of the locking system, and transmit lock signals to these. In addition to or alternatively to the locking system, it is preferred that the end stage system is embodied such that forbidden switch states are not generated (from the outset).

It is noted at this point that in this case, although the switches are driven by means of signals, strictly speaking, what is concerned here is a feedback control system. Typically (known in the prior art), there exists a controlled system that comprises the GPA and constrains the latter in terms of its dynamics (by reducing the possible switching states). In general, however, a setpoint is specified, and upon the output of the current to the coil, a check is once again carried out to verify whether the setpoint has been reached. Based on the check, the output current is then correctively readjusted if necessary by means of other switch settings. The feedback control system, therefore, attempts to guide the controlled system such that the actual value corresponds to the setpoint. However, the present disclosure engages with the interconnection of the bridge units and their “forbidden” states; therefore lies basically in the middle of the switching part of the feedback control system. In this context, in order to prevent misunderstandings, the terms “switching unit” and “switching signals” are used, which should be regarded as part of the higher-level feedback control system.

A preferred end stage system is characterized in that each bridge unit comprises an H-bridge having at least four switches. The end stage system then preferably comprises a switching unit that is configured to switch the switches of the bridge units according to a respective predefined switching pattern. In order to boost the power, up to 7 IGBTs (bipolar field-effect transistors) per switch are often connected in parallel in an H-bridge. In this case, there are therefore 28 IGBTs in an H-bridge, of which 7 always act in a block as a switch. It is preferred in this case that, in an end stage system, according to the aspects of the disclosure, the locking system is configured to suppress specified switching combinations of the switching pattern of the switching unit.

A preferred end stage system comprises an activation control unit, which is configured to activate or deactivate a bridge unit, preferably every bridge unit (block by block for each end stage). It is preferred in this case that with an end stage as claimed in claim 7, the activation control unit is configured to activate or deactivate a number of bridge units (preferably all the bridge units of the end stage) by means of the locking system, preferably by its being configured to activate or deactivate all lock units connected to an end stage block by block.

According to a preferred aspect of the method, an activation pattern is specified according to which the switching signals for the gradient coils are activated block by block, preferably so that switching signals for two of the gradient coils are active at any point in time and the switching signals for a further number of gradient coils are inactive, wherein the switches of the bridge units are switched according to a predefined activation pattern and the desired switching combinations. In this case, the activation pattern specifies which switch groups are active at which point in time and which are inactive.

The activation unit can, by all means, be part of the above-cited higher-level feedback control system. In this regard, the individual cylinders can be activated in particular according to the required current slope in the axes. This has the advantage compared to a fixedly specified activation that potentially “slope reserves” can be distributed among the axes situationally.

### BRIEF DESCRIPTION OF THE DRAWINGS

The aspects of the disclosure are explained once again in more detail in the following with the aid of exemplary aspects and with reference to the attached figures. Like components are labeled herein with the same reference numerals in the different figures. The figures are generally not to scale. In the figures:

FIG. 1 shows a schematic view of a magnetic resonance tomography system comprising a device according to an exemplary aspect of the disclosure,

FIG. 2 shows an end stage with a gradient coil,

FIG. 3 shows three end stages for three gradient coils according to the prior art,

FIG. 4 shows an example of an end stage system according to the aspects of the disclosure comprising three gradient coils,

FIG. 5 shows the interconnection of the H-bridges of the bridge units of an end stage system according to the aspects of the disclosure,

FIG. 6 shows an example of a forbidden switching combination of the H-bridges of the bridge units of an end stage system according to the aspects of the disclosure,

FIG. 7 shows a table containing forbidden switching combinations of the X end stage,

FIG. 8 shows a table containing forbidden switching combinations between X end stage and Y end stage,

FIG. 9 shows a table containing forbidden switching combinations between X end stage and Z end stage,

FIG. 10 shows a switching unit for bridge units,

FIG. 11 shows a lock unit of a locking unit for suppressing switching signals,

FIG. 12 shows an example of an activation pattern,

FIG. 13 shows an end stage system according to the aspects of the disclosure comprising three gradient coils, switching unit, locking system, and activation control unit, and

FIG. 14 shows the workflow of the method as a block diagram.

### DETAILED DESCRIPTION

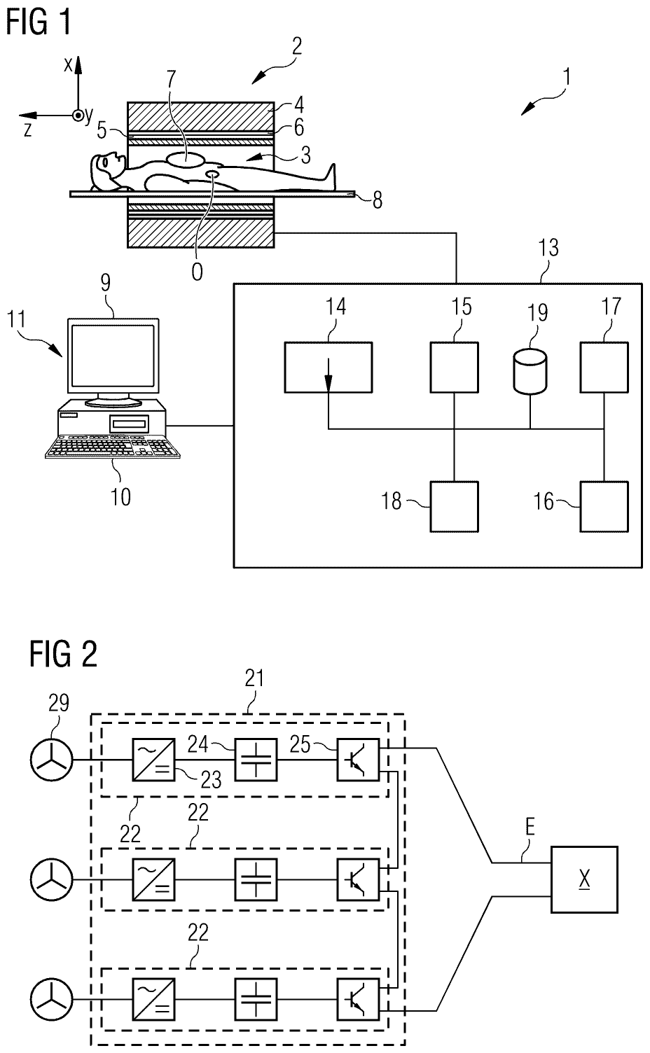

FIG. 1 shows a rough schematic view of a magnetic resonance tomography system 1. This comprises firstly the actual magnetic resonance scanner 2 having an examination chamber 3 or patient tunnel (regarded here as receiving zone 3) into which a patient or test person in whose body the actual examination object O is located is introduced, positioned on a couch 8.

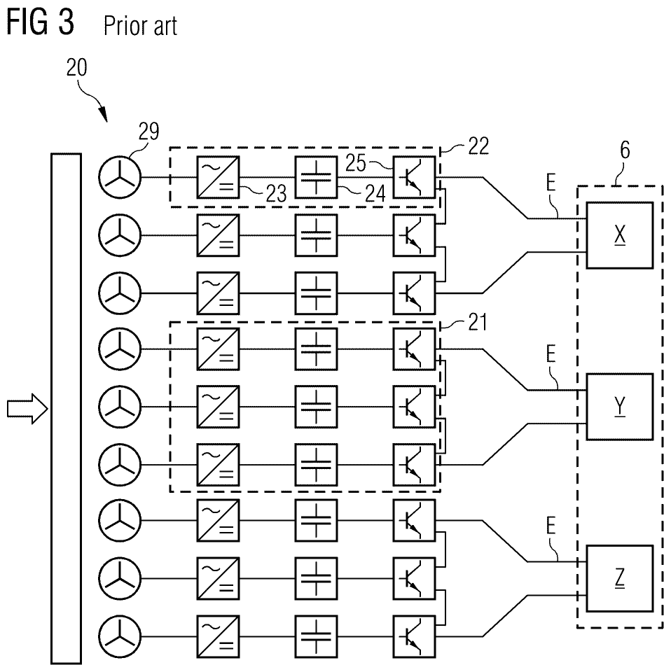

The magnetic resonance scanner 2 is equipped in the conventional manner with a basic field magnet system 4, a gradient system 6, as well as an RF transmit antenna system 5 and an RF receive antenna system 7. In the exemplary aspect shown, the RF transmit antenna system 5 is a whole-body coil permanently integrated in the magnetic resonance scanner 2, whereas the RF receive antenna system 7 consists of local coils that are to be arranged on the patient or test person (in this case symbolized by just a single local coil). Basically, however, the whole-body coil can also be used as an RF receive antenna system, and the local coils as an RF transmit antenna system, provided said coils can be switched over in each case into different modes of operation. In this case, the basic field magnet system 4 is embodied in the conventional manner such that it generates a basic magnetic field in the longitudinal direction of the patient, i.e., along the longitudinal axis of the magnetic resonance scanner 2 extending in the z-direction. The gradient system 6 comprises individually drivable gradient coils X, Y, Z (see, for example, FIG. 3) in the conventional manner in order to enable mutually independent gradients to be switched in the x-, y-, or z-direction.

The magnetic resonance tomography system shown here is a whole-body system comprising a patient tunnel into which a patient can be introduced completely. In principle, however, the aspects of the disclosure can also be used on other magnetic resonance tomography systems. The only essential factor is that corresponding images of the examination object O can be produced.

The magnetic resonance tomography system 1 additionally comprises a central control device 13, which is used for controlling the MR system 1. Said central control device 13 comprises a sequence control unit 14. With the latter unit, the succession of radiofrequency pulses (RF pulses) and gradient pulses is controlled in accordance with a chosen pulse sequence or a succession of multiple pulse sequences for the acquisition of a plurality of slices in the acquisition region within a measurement session. Such a pulse sequence can be predefined and parameterized within a measurement or control protocol, for example. Typically, different control protocols for different measurements or measurement sessions are stored in a storage device 19 and can be selected (and possibly modified if necessary) by an operator and then used for conducting the measurement.

The examination region can be specified on the basis of selected pulse sequences or on the basis of the positioning of the above-cited RF receive antenna system 7.

In order to output the individual RF pulses of a pulse sequence, the central control device 13 has a radiofrequency transmit device 15 which generates the RF pulses, amplifies them, and feeds them into the RF transmit antenna system 5 via a suitable interface (not shown in detail).

To control the gradient coils X, Y, Z of the gradient system 6 in order to switch the gradient pulses appropriately in accordance with the predefined pulse sequence, the control device 13 has a gradient system interface 16. The diffusion gradient pulses and spoiler gradient pulses could be applied via said gradient system interface 16. The sequence control unit 14 communicates in a suitable manner, for example by transmitting sequence control data, with the radiofrequency transmit device 15 and the gradient system interface 16 in order to execute the pulse sequence. It can be assumed in this case that the gradient system interface 16 transmits the control pulses for switching the switches 28 of the bridge units 25, i.e., comprises the switching unit 30 according to FIG. 10.

The control device 13 also comprises a radiofrequency receive device 17 (likewise communicating in a suitable manner with the sequence control unit 14) in order to receive magnetic resonance signals in a coordinated manner by means of the RF receive antenna system 7 within the readout windows predefined by the pulse sequence and thereby to acquire the raw data.

In this case, a reconstruction unit 18 accepts the acquired raw data and reconstructs magnetic resonance image data therefrom. This reconstruction also is generally performed on the basis of parameters which can be predefined in the respective measurement or control protocol. This image data can then be stored in a storage device 19, for example.

The details of how suitable raw data is acquired by radiating in RF pulses and switching gradient pulses and how MR images or parameter maps are reconstructed therefrom are generally known to the person skilled in the art and are therefore not explained in greater depth here.

During an MRT scan, currents flow through the gradient coils X, Y, Z of the gradient system 6 (not constantly but as an alternating function), which currents the coils receive from a gradient amplifier (not shown here) (or an end stage system 20 according to the aspects of the disclosure). The bridge units 25 of the end stages 21 are then switched by the gradient system interface 16.

An example of the construction of an end stage 21 with a gradient coil X connected to the end stage output E is shown in FIG. 2. The end stage 21 in this case comprises three cylinders 22. Depending on the application, more or fewer cylinders may be present, an uneven number being preferred in order to suppress certain oscillation states.

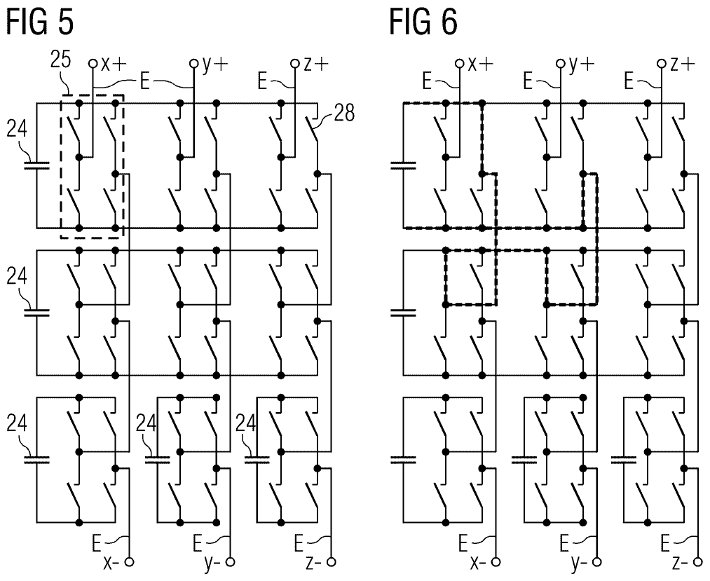

In this example, the cylinders each comprise a current conversion unit 23 (rectifier) and a capacitor unit 24, as well as a bridge unit 25 coupled to said capacitor unit 24, wherein the three bridge units 25 are interconnected with one another in series, as is shown for example in FIG. 5, which will be addressed in more detail later. This interconnection is prior art. By means of the bridge units 25, charges of the capacitor units 24 can be tapped according to the settings of the switches 28 of the bridge units 25 and used for current pulses for the gradient coil X. In this case, it is possible, in particular, to add together the voltages of the capacitor units 24.

FIG. 3 shows three end stages 21 according to FIG. 2 for three gradient coils X, Y, Z of a gradient system 6. The three end stages form a gradient amplifier according to the prior art. The power supply is indicated on the left by an arrow. For example, current flows through a transformer coil and the nine secondary coils of the nine current conversion units 23 engage at the magnetic yoke of the transformer (indicated by the box on the left). Altogether, nine complete cylinders 22 are required for said gradient amplifier, all of which are galvanically isolated from one another.

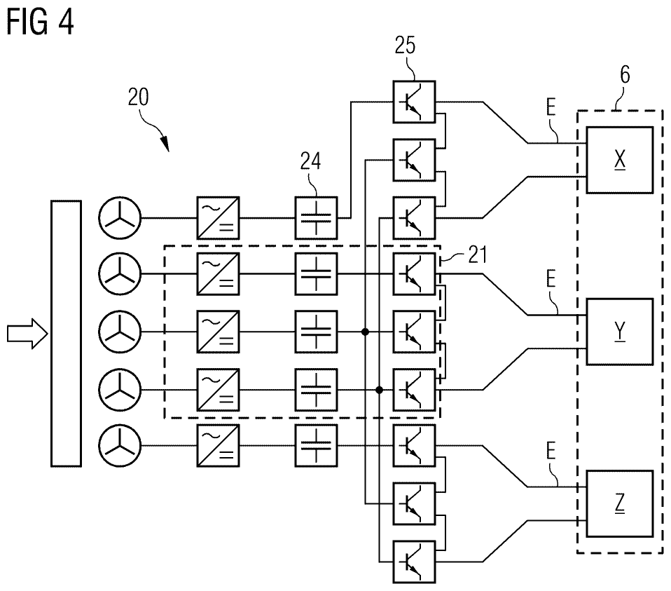

FIG. 4 shows an example of an end stage system 20 according to the aspects of the disclosure comprising three gradient coils X, Y, Z of a gradient system 6. Here, too, each of the end stages 21 comprises a plurality of cylinders as shown in FIG. 2. In contrast to FIG. 3, however, there are two capacitor units 24, each of which is connected to a bridge unit 25 of each of the three end stages 21. In this example, therefore, the gradient amplifier basically comprises three end stages 21, two bridge units 25 of each of the end stages 21 being connected to the same capacitor unit 24 in each case. In this arrangement, the first (lowest) bridge unit 25 of each of the end stages 21 in each case is connected to the same first capacitor unit 24, and in addition, a second (middle) bridge unit 25 of each of the end stages 21 in each case is connected to the same second capacitor unit 24.

In this example, each end stage output E is formed from three bridge units 25 interconnected in series. However, there could also be five or seven (or basically any arbitrary number). In the case illustrated here, four parts of cylinders, namely the current conversion unit as well as the capacitor unit, can be saved in total compared to FIG. 3. With five or seven cylinders, it can by all means be more.

The bridge unit 25, arranged uppermost in the figure, of each of the end stages 21 is galvanically isolated from the other end stages 21. Although theoretically these could also be operated like the others on one capacitor unit, this could lead in practice to too great a restriction on the possible operating modes, As is shown in greater detail below, certain switching configurations of the bridge units 25 can lead to undesirable states (short circuits, load short circuits), which should be avoided. A galvanic isolation ensures a greater number of possible switch settings without unwanted states. The galvanic isolation preferably relates to a bridge unit 25 at the start or at the end of the series connection of the end stage 21 in question. This has a positive impact in terms of reducing unwanted states.

FIG. 5 shows the interconnection of the H-bridges of the bridge units of an end stage system according to the aspects of the disclosure. The end stage outputs (designated by x, y, and z) for the three gradient coils X, Y, Z are shown from left to right. In this arrangement, there is a coil input (“+”) according to specification and a coil output (“−”) according to specification.

The switches 28 of the bridge units 25 embodied as H-bridges are all open in this case. The four inputs of the bridge units 25 are in each case connected in pairs to the poles of the capacitor unit 24, while the two outputs are interconnected such that one output is connected to the respective preceding entity (from below) and the other output is connected to the succeeding entity (top). In this way, given a suitable switch setting, for example, all three capacitor units 24 of a string can be connected in series to the end stage outputs E, or alternatively, just one or two.

In this example, the lower H-bridges are galvanically isolated from one another, and each is connected to its own capacitor unit 24. In FIG. 3, these bridge units 25 would correspond to the upper ones in each case.

FIG. 6 shows the circuit of FIG. 5 with an example of a forbidden switching combination of the H-bridges of the bridge units 25. In this case, some of the switches 28 are closed such that the thick dashed path represents a short-circuit of the top capacitor unit 24. With other switch settings, two capacitor units 24 could be short-circuited with one another and in turn with other end stage outputs E.

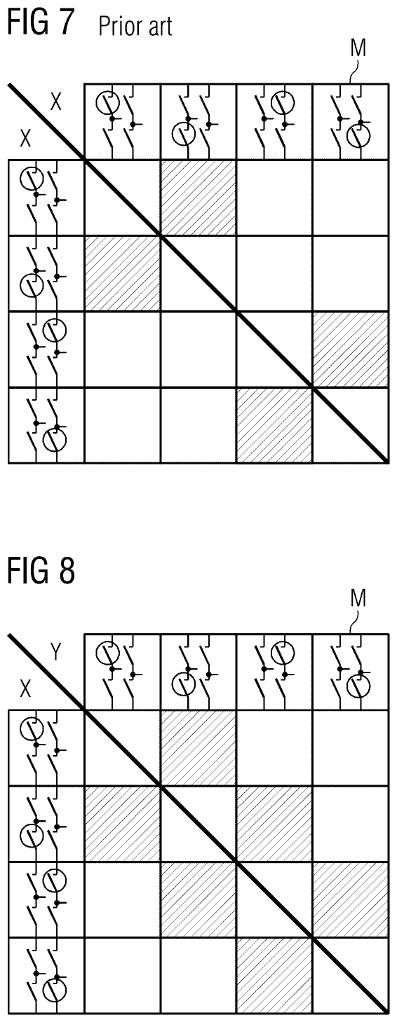

FIG. 7 shows a table containing forbidden switching combinations of the X end stage 21. These are the typical forbidden switch settings within a string (X-X), as they are known in the prior art. As can be inferred already in FIG. 5, in an H-bridge the two switches 28 disposed one directly above the other must not be closed to ensure that the capacitor unit is not short-circuited. This is furthermore achieved by means of the buffer/inverter pair at the output of the switching unit 30 of FIG. 10.

As can be gathered from the table, switching combinations of switches disposed directly above one another are forbidden (hatched table cell).

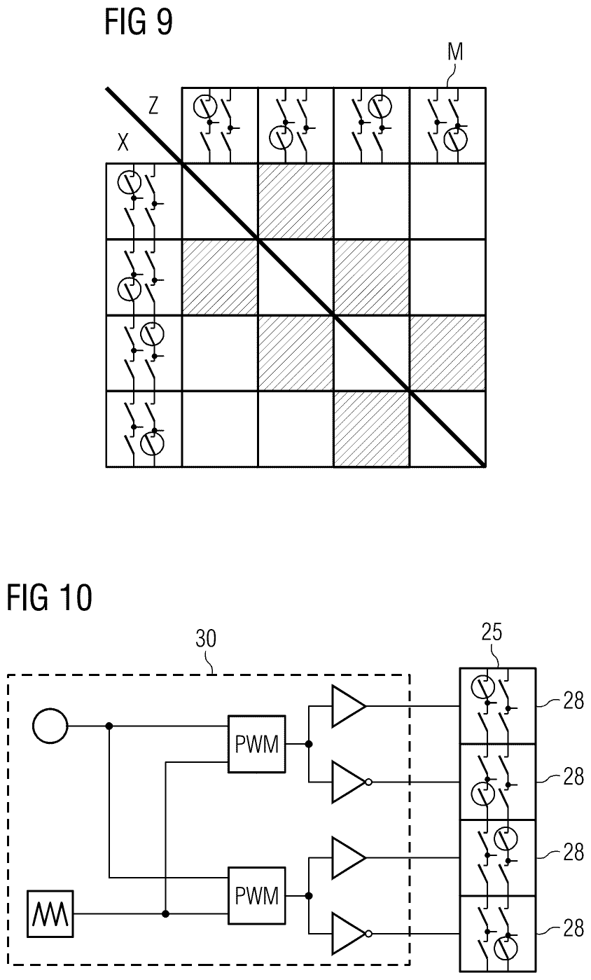

As FIG. 6 indicates, switching combinations of switches of different strings may also be forbidden since they lead to undesirable states. These are indicated (hatched cells) in FIGS. 8 and 9. Forbidden switching combinations between the Y and Z string would look accordingly.

FIG. 8 shows a table containing forbidden switching combinations between X end stage and Y end stage. If the switch at top left were to be designated by “1”, the switch at bottom left by “2”, the switch at top right by “3”, and the switch at bottom right by “4”, then the switching combinations X1+Y2, X2+Y1, X2+Y3, X3+Y2, X3+Y4 and X4+Y3 would be forbidden. This table, like those that follow also, is simply an example for three cylinders 21. If more cylinders are present, this table would continue diagonally.

FIG. 9 shows a table containing forbidden switching combinations between the X end stage and the Z end stage. In this case the switching combinations X1+Z2, X2+Z1, X2+Z3, X3+Z2, X3+ZA and X4+Z3 are forbidden.

With regard to the Y and Z strings, the switching combinations Y1+Z2, Y2+Z1, Y2+Z3, Y3+Z2, Y3+ZA, and Y4+Z3 would be forbidden.

FIG. 10 shows a switching unit 30 for bridge units. This is basically prior art and could be arranged in the gradient system interface 16. A frequency generator (indicated at bottom left by a triangle pattern) supplies pulse width modulators (PWMs) with a signal, and the desired signal shape is input at top left. The pulse width modulators then emit switching signals for the switches 28 of a bridge unit 25, and moreover, by means of a buffer and an inverter in each case, according to the table shown in FIG. 7, alternately so that switches 28 disposed directly above one another do not switch simultaneously.

FIG. 11 shows a lock unit 27 for suppressing switching signals that can be switched between each of the outputs of the switching unit 30 of FIG. 10 and the respective switch 28. This is basically an AND gate which has a normal and an inverted output (i.e., an AND/NAND gate). These gates may be present in the form of hardware or software. In addition to the input I for the switching signal, the lock unit also has further inputs I in order to suppress the switching signal. These are present preferably in the form of inverted output signals of the other lock units 27. If, for example, the input signal for this lock unit were the switching signal for X1, then the inverted output signal according to the tables of FIGS. 8 and 9 would go to the lock units for Y2 and Z2 in order to suppress the switching signals for Y2 and Z2 if X1 is switched. The interconnection of the lock units 27 can therefore be derived directly from FIGS. 8 and 9 and the analog locking of the switching signals for Y and Z.

The interconnected lock units 27 together form the locking system 26, which is depicted in FIG. 13.

Also connected to the lock unit 27 is an activation control unit 31, which is configured to activate or deactivate a bridge unit 25 by way of the lock units 27. It could be connected to a separate “Enable” input of the lock units 27 or to an input I of the lock units 27.

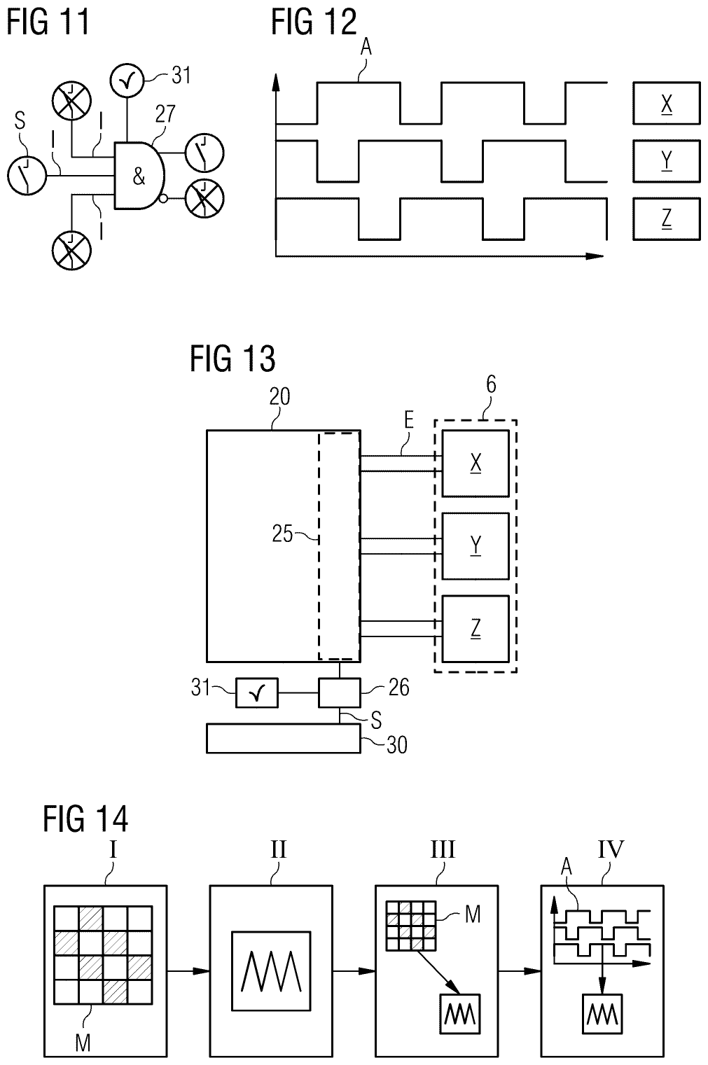

FIG. 12 shows an example scheme, an “activation pattern” A, which shows how the lock units 27 could be switched block by block. The lock units 27 for the end stage outputs for the X gradient coil X could be switched block by block according to the topmost curve, the lock units 27 for the end stage outputs for the Y gradient coil Y block by block according to the middle curve and the lock units 27 for the end stage outputs for the Z gradient coil Z block by block according to the bottom curve, wherein a bottom signal in each case causes an inactivity and a top signal an activity. It can be seen that two coils are always active here, which potentially can also have repercussions on forbidden switch settings.

FIG. 13 shows an end stage system 20 according to the aspects of the disclosure comprising three gradient coils X, Y, Z, a switching unit 30 according to FIG. 10, a locking system 26 comprising lock units according to FIG. 11 and an activation control unit 31, which activates or deactivates the lock units 27 of the locking system 27 block by block according to the curves of FIG. 12. The switching unit 30 sends a switching signal S to the bridge units 25, wherein said switching signal S comprises the settings of all the switches 28 of the bridge units 25 at a specific point in time. This switching signal S is filtered by the locking system 26 such that only permitted switch settings are allowed through. In the locking system 26, individual lock units 27 are activated or blocked by means of the activation control unit 31 block by block, such that the switching signal S is further filtered still as a result.

FIG. 14 shows the workflow of the method for controlling an end stage system 20 according to FIG. 13 as a block diagram.

In step I, a table M of forbidden switching combinations for the bridge units 25 is specified.

In step II, a data stream having a target current profile for an examination is received, and target switching combinations are determined by means of which the bridge units 25 must be switched in order to achieve the target current profile.

In step III, forbidden switching combinations of the target switching combinations are suppressed based on the specified table M.

In step IV (which can be performed in parallel with step III), the lock units are additionally activated and deactivated block by block according to an activation pattern A and, if necessary, further target switching combinations are suppressed as a result.

The control commands for switching the switches of the bridge units 25 are then output.

Finally, it is pointed out once again that the aspects of the disclosure described in detail in the foregoing simply concerns exemplary aspects which can be modified in the most diverse ways by the person skilled in the art without leaving the scope of the invention. Furthermore, the use of the indefinite articles “a” or “an” does not rule out the possibility that the features in question may also be present more than once. Similarly, terms such as “unit” do not rule out the possibility that the components in question may consist of a plurality of cooperating subcomponents, which, if necessary, may also be spatially distributed. The term “a number” is to be read as “at least one”. Independent of the grammatical term usage, individuals with male, female, or other gender identities are included within the term.

1. An end stage system for a gradient amplifier comprising a plurality of end stages for different gradient coils, wherein each of the end stages has a plurality of cylinders, and each cylinder comprises at least one circuit composed of a capacitor unit and at least one bridge unit, wherein a plurality of bridge units are interconnected in series as an end stage output, and wherein bridge units of at least two different end stages are connected to the same capacitor unit.

2. The end stage system as claimed in claim 1, wherein the gradient amplifier comprises at least three end stages, and at least one bridge unit of each of the end stages is connected to the same capacitor unit.

3. The end stage system as claimed in claim 1, wherein each end stage output comprises the same number of bridge units interconnected in series.

4. The end stage system as claimed in claim 1, wherein the series connection of the bridge units of each end stage output has a functional order which is determined by magnetic fields of the gradient coils connected according to specification to the end stages and bridge units of at least two different end stages which are connected to the same capacitor unit are in each case bridge units of the same or similar type in respect of their position in the order.

5. The end stage system as claimed in claim 1, wherein at least one bridge unit of each of the end stages is galvanically isolated from the other end stages.

6. The end stage system as claimed in claim 1, further comprising a locking system which prevents specified switching combinations of the bridge units that lead to a short circuit between terminals of a capacitor unit, lead to a direct connection between the terminals of two capacitor units, or lead to load short circuits.

7. The end stage system as claimed in claim 6, wherein the locking system for each switching signal of a switch of a bridge unit comprises a lock unit comprising an arrangement of logic gates, wherein each lock unit comprises an input for a signal and a number of inputs for lock signals, and an output for the switching signal.

8. The end stage system as claimed in claim 1, wherein each bridge unit has an H-bridge comprising at least four switches, and wherein the end stage system comprises a switching unit (30) which is configured to switch the switches of the bridge units according to a respectively predefined switching pattern.

9. The end stage system as claimed in claim 1, further comprising an activation control unit which is configured to activate or deactivate a bridge unit.

10. A method for controlling an end stage system as claimed in claim 1, comprising:
specifying a list or table of forbidden switching combinations for the bridge units of the end stage system;
receiving a data stream having a target current profile for an examination;
determining target switching combinations with which the bridge units must be switched in order to achieve the target current profile; and
outputting control commands for switching the switches of the bridge units according to the target switching combinations, wherein forbidden switching combinations are suppressed.

11. The method as claimed in claim 10, wherein an activation pattern is specified according to which the switching signals for the gradient coils are activated block by block, wherein the switches of the bridge units are switched according to the activation pattern and desired switching combinations.

12. A gradient system for a magnetic resonance tomography system comprising gradient coils and an end stage system as claimed in claim 1, wherein a gradient coil is connected in each case to an end stage output of an end stage of the end stage system.

13. A magnetic resonance tomography system comprising a gradient system as claimed in claim 12.
